(19) United States
(12) Patent Application Publication
(10) Pub. No.: US 2018/0310417 A1
(43) Pub. Date: Oct. 25, 2018

(54) CIRCUIT BOARD STRUCTURE AND METHOD FOR FORMING THE SAME

(71) Applicant: Nan Ya Printed Circuit Board Corporation, Taoyuan City (TW)

(72) Inventors: Cheng-Hsieng Lin, Taoyuan City (TW); Sheng-Ping Wang, Taoyuan City (TW); Ming-Chieh Ma, Taoyuan City (TW); Yin-Chih Liu, Taoyuan City (TW)

(21) Appl. No.: 15/700,068

(22) Filed: Sep. 8, 2017

(30) Foreign Application Priority Data
Apr. 21, 2017 (TW) 106113408

(51) Int. Cl. H05K 3/42; H01L 21/48; H01L 21/683; H01L 23/498; H05K 1/11; H05K 3/06; H05K 3/18; H05K 3/00

(52) U.S. Cl. CPC H05K 3/425; H05K 1/09; H01L 21/6835; H01L 21/481; H01L 23/49827; H01L 23/49838; H05K 1/113; H05K 3/064; H05K 3/423; H05K 3/181; H05K 3/007; H05K 3/0097; H01L 2221/68345; H01L 2221/68359; H01L 23/49866; H05K 2201/09854; H05K 2201/09509; H01L 21/486

(57) ABSTRACT

A circuit board structure and its forming method are provided. The circuit board structure includes a dielectric layer and a first wiring layer embedded in the dielectric layer. The first wiring layer includes a plurality of conductive contact pads exposed on the upper surface of the dielectric layer. The circuit board structure also includes a plurality of metal pillars. Each of the metal pillars is formed on and is in direct contact with one of the conductive contact pads. The circuit board structure also includes a first insulating passivation layer and a second insulating passivation layer formed on the upper surface and the lower surface of the dielectric layer. The first insulating passivation layer includes a first opening exposing the metal pillars and the conductive contact pads, and the second insulating passivation layer includes a second opening.

### CROSS REFERENCE TO RELATED APPLICATIONS

This Application claims priority of Taiwan Patent Application No. 106113408, filed on Apr. 21, 2017, entitled “circuit board structure and method for forming the same”, which is hereby incorporated by reference in its entirety.

### BACKGROUND OF THE INVENTION

### Field of the Invention

The present invention relates to a circuit board structure and in particular to a circuit board structure of high good yield and low cost and a method for forming the same.

### Description of the Related Art

Printed circuit boards (PCB) are universally used in various electronic devices. PCBs can not only fixate various electronic components, but also provide each electronic component with the means to form an electrical connection.

Today, consumers demand that their electronic products be lightweight, thin, small, and inexpensive. As a result, PCBs are required to have a high wiring density, and their manufacturing process must produce a high good yield at a low manufacturing cost. Therefore, it is still necessary to modify the structure and process of a PCB so as to raise the good yield and lower the manufacturing cost.

### BRIEF SUMMARY OF THE INVENTION

Some embodiments of the present invention provide a circuit board structure, including a dielectric layer, a first wiring layer, a plurality of metal pillars, a first insulating passivation layer, and a second insulating passivation layer. The dielectric layer has an upper surface and a lower surface. The first wiring layer is embedded in the dielectric layer and includes a plurality of conductive contact pads. The conductive contact pads are exposed on the upper surface of the dielectric layer. Each of the metal pillars is formed on, and is in direct contact with, one of the conductive contact pads. The first insulating passivation layer is formed on the upper surface of the dielectric layer and includes a first opening that exposes the metal pillars and the conductive contact pads. The second insulating passivation layer is formed on the lower surface of the dielectric layer and includes a second opening.

Some other embodiments of the present invention provide a method for forming a circuit board structure, including: forming a first patterned photoresist layer on a carrier substrate, wherein the first patterned photoresist layer includes a plurality of patterned photoresist structures; depositing a conductive material on the carrier substrate to form a conductive barrier layer surrounding the patterned photoresist structures, wherein the conductive barrier layer and the patterned photoresist structures are the same height; removing the patterned photoresist structures to form a plurality of recesses in the conductive barrier layer; electroplating a metal material on the conductive barrier layer to fill the recesses to form a plurality of metal pillars and a first wiring layer, wherein the metal pillars are in the recesses and the first wiring layer includes a plurality of conductive contact pads, and wherein the metal material is different from the conductive material; forming a dielectric layer on the first wiring layer, wherein the dielectric layer covers the first wiring layer; removing the carrier substrate; performing an etch process to remove the conductive barrier layer, wherein the metal pillars protrude from the upper surface of the dielectric layer and the upper surface of the dielectric layer exposes the conductive contact pads; forming a first insulating passivation layer on the upper surface of the dielectric layer, wherein the first insulating passivation layer has a first opening, and the first opening exposes the metal pillars and the conductive contact pads; and forming a second insulating passivation layer on the lower surface of the dielectric layer, wherein the second insulating passivation layer includes a second opening.

Other embodiments of the present invention provide a method for forming a circuit board structure, including: forming an upper patterned photoresist layer on an upper surface of a carrier substrate, and forming a lower patterned photoresist layer on a lower surface of the carrier substrate, wherein the upper patterned photoresist layer includes a plurality of upper patterned photoresist structures, and the lower patterned photoresist layer includes a plurality of lower patterned photoresist structures; depositing a conductive material on the upper surface and the lower surface of the carrier substrate to form an upper conductive barrier layer surrounding the upper patterned photoresist structures and to form a lower conductive barrier layer surrounding the lower patterned photoresist structures, wherein the upper conductive barrier layer and the upper patterned photoresist structures have a first height, and the lower conductive barrier layer and the lower patterned photoresist structures have a second height; removing the upper patterned photoresist structures and the lower patterned photoresist structures to form a plurality of upper recesses in the upper conductive barrier layer and to form a plurality of lower recesses in the lower conductive barrier layer; electroplating a metal material on the upper conductive barrier layer to fill the upper recesses to form a plurality of upper metal pillars and an upper wiring layer; electroplating the metal material on the lower conductive barrier layer to fill the lower recesses to form a plurality of lower metal pillars and a lower wiring layer; forming an upper dielectric layer on the upper wiring layer, and forming a lower dielectric layer on the lower wiring layer; removing the carrier substrate to form an upper circuit board unit that includes the upper conductive barrier layer, the upper metal pillars, the upper wiring layer and the upper dielectric layer, and to form a lower circuit board unit that includes the lower conductive barrier layer, the lower metal pillars, the lower wiring layer and the lower dielectric layer; performing an etch process to remove the upper conductive barrier layer of the upper circuit board unit and to remove the lower conductive barrier layer of the lower circuit board unit; forming an upper first insulating passivation layer on an upper surface of the upper circuit board unit, wherein the upper first insulating passivation layer has an upper first opening, and the upper first opening exposes the upper metal pillars and a portion of the upper wiring layer; forming an upper second insulating passivation layer on a lower surface of the upper circuit board unit, wherein the upper second insulating passivation layer includes an upper second opening; forming a lower first insulating passivation layer on an upper surface of the lower circuit board unit, wherein the lower first insulating passivation layer has a lower first opening, and the lower first opening exposes the lower metal pillars and a portion of the lower wiring layer; and forming a lower second insulating passivation layer on a lower surface of the lower circuit board unit, wherein the lower second insulating passivation layer includes a lower second opening.

A detailed description is given in the following embodiments with reference to the accompanying drawings.

The invention can be more fully understood by referring to the following detailed description and examples with references made to the accompanying drawings, wherein:

### BRIEF DESCRIPTION OF THE DRAWINGS

The present invention can be more fully understood by reading the subsequent detailed description and examples with references made to the accompanying drawings, wherein:

FIGS. 1A to 1L are cross-sectional views of various intermediate stages of forming a circuit board structure according to some embodiments.

FIGS. 2A to 2C are cross-sectional views of various intermediate stages of forming a circuit board structure according to some embodiments.

FIGS. 3A to 3C are cross-sectional views of various intermediate stages of forming a circuit board structure according to some embodiments.

FIG. 4 is a cross-sectional view of patterned photoresist structures according to some embodiments.

FIG. 5 is a cross-sectional view of patterned photoresist structures according to some embodiments.

FIGS. 6A to 6D are cross-sectional views of various intermediate stages of forming a circuit board structure according to some embodiments.

### DETAILED DESCRIPTION OF THE INVENTION

In order to make the above and other purposes, features, advantages of the invention fully understood, examples are provided herein and discussed in detail with the accompanying drawings. However, those skilled in the art will realize that various feature structures are only used for illustration, and are not drawn to scale. In fact, the relative scales of various feature structures can be increased or decreased arbitrarily in order to make the illustration more clear. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

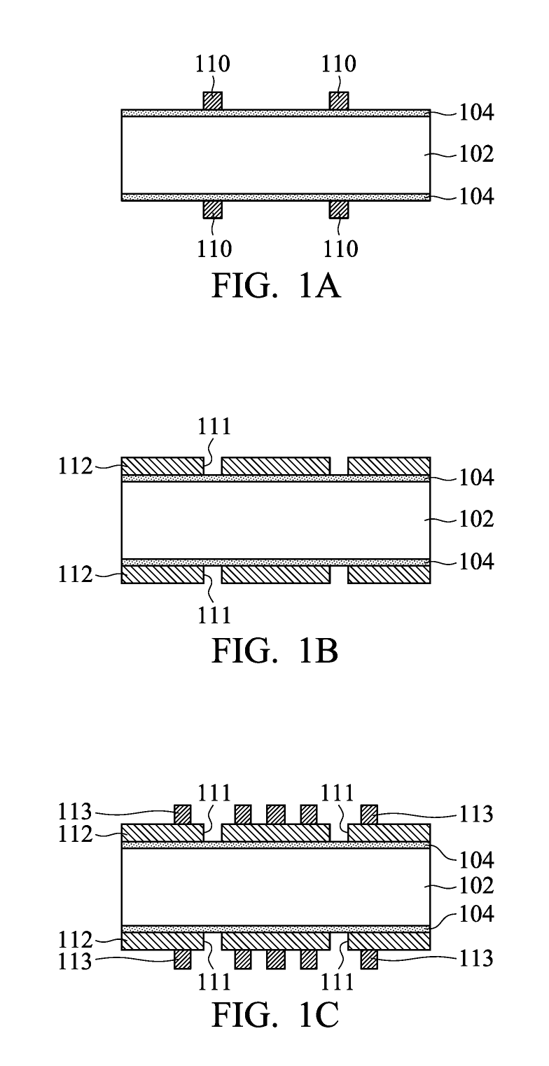

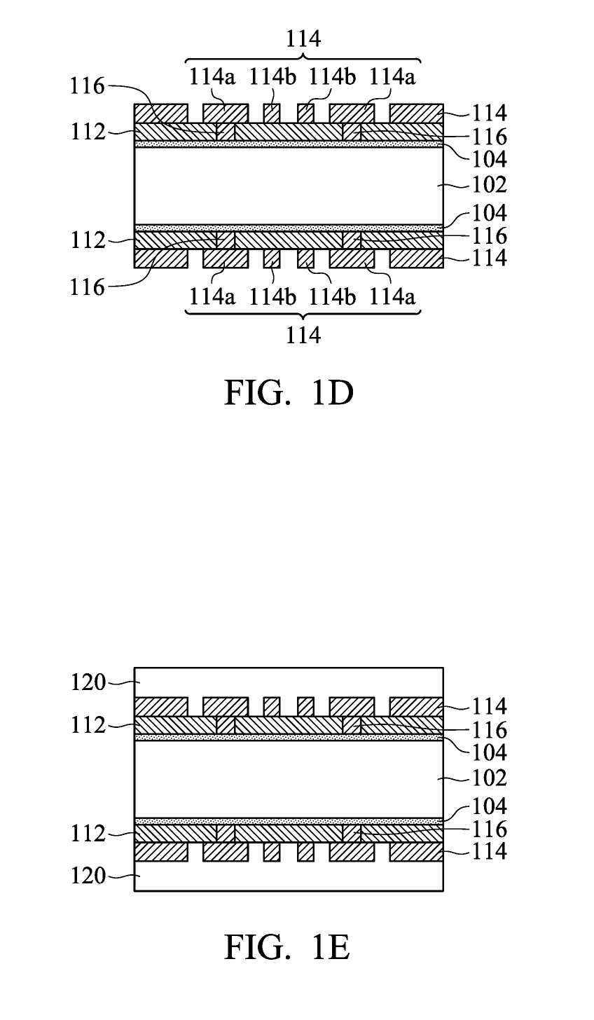

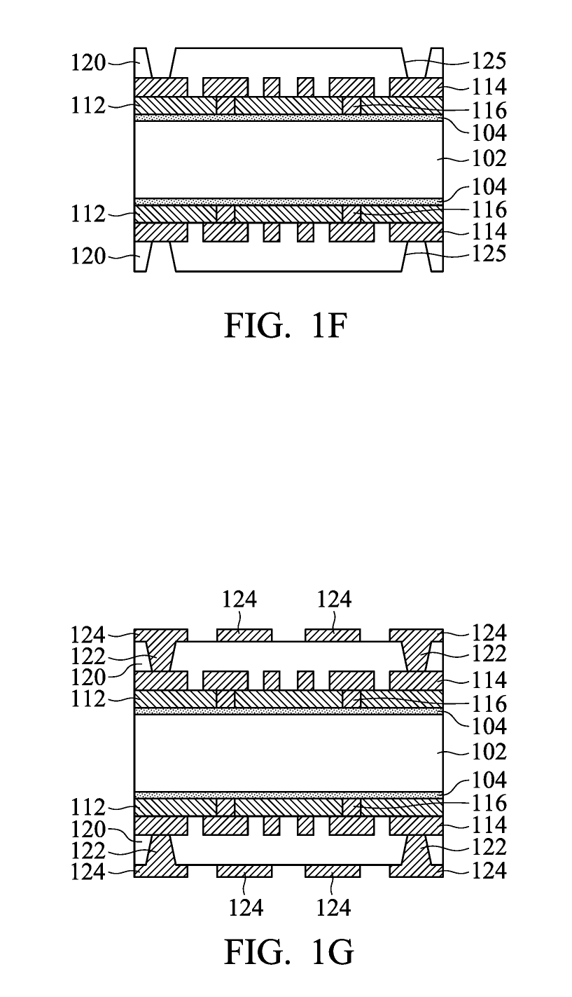

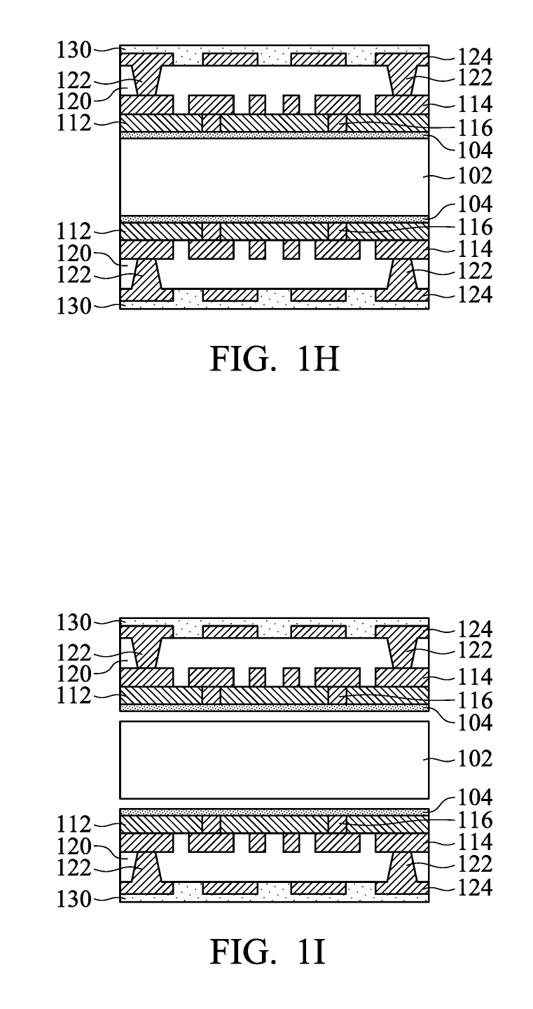

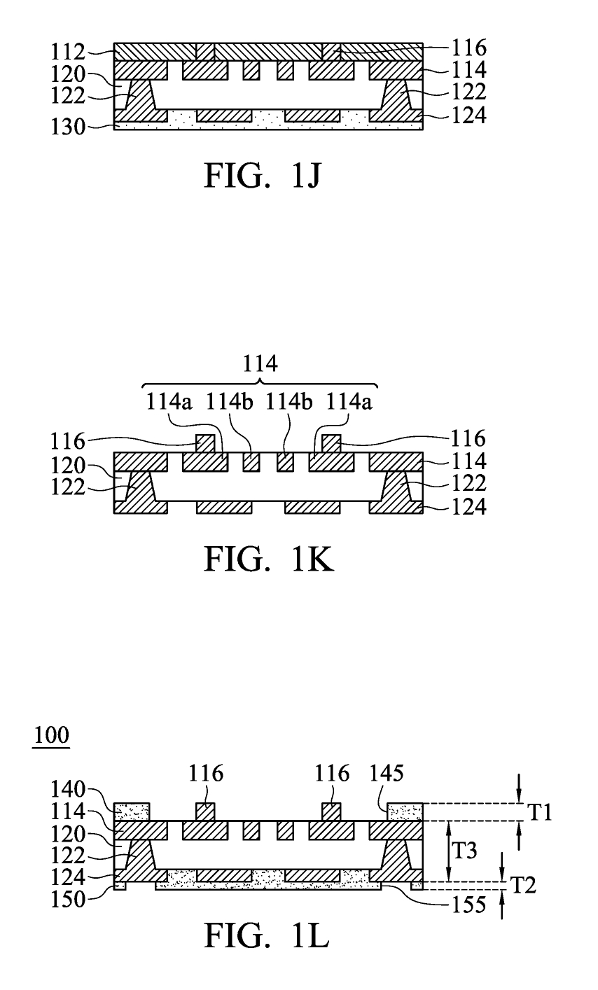

Some embodiments of the present invention provide circuit board structures and methods for forming the same. FIGS. 1A to 1L are cross-sectional views of various intermediate stages of forming a circuit board structure according to some embodiments.

Referring to FIG. 1A, a carrier substrate 102 whose upper surface and lower surface respectively have stripping layers 104 is provided. The carrier substrate 102 has rigidity and can support a circuit board structure which will be formed subsequently. The stripping layers 104 can be easily removed from the carrier substrate 102, and thus are helpful in the subsequent removal of the carrier substrate 102. In some embodiments, the stripping layers 104 may be made of a conductive material, such as copper foil. The materials of the stripping layer 104 and the carrier substrate 102 may be any suitable known material, and it is not discussed herein in any further detail.

Subsequently, a photoresist layer is coated on two sides of the carrier substrate 102, and an image transfer process is performed to form a first patterned photoresist layer on the upper surface and the lower surface of the carrier substrate 102, as shown in FIG. 1A. The image transfer process may include a known photolithography process or any other suitable process. The material of the photoresist layer may be any known photoresist material, which is not discussed herein in any further detail.

Still referring to FIG. 1A, the first patterned photoresist layer includes a plurality of patterned photoresist structures 110. The patterned photoresist structures 110 are helpful in subsequently forming metal pillars, which is discussed in detail below.

In the embodiments, the processes performed on the upper surface and the lower surface of the carrier substrate 102 are both the same, and the shape and relative position of each component on the upper surface of the carrier substrate 102 uses the carrier substrate 102 as a symmetric plane, and is symmetric to the shape and relative position of each component on the lower surface of the carrier substrate 102. In order to simplify the illustration, hereinafter only the components on the upper surface of the carrier substrate 102 are discussed.

Referring to FIG. 1B, a conductive material is deposited on the carrier substrate 102 to form a conductive barrier layer 112 surrounding the patterned photoresist structures 110. The conductive material may include nickel, cobalt, zinc, aluminum, graphite, a conductive polymer or a conductive metal oxide. In some embodiments, the conductive material is nickel or a nickel alloy. In some other embodiments, the conductive material is cobalt or a cobalt alloy.

A suitable deposition process may be selected by the conductive material which is selected. For example, the suitable deposition process may include chemical vapor deposition process, physical vapor deposition process, sputtering process, evaporation process, electroplating process, any other suitable deposition process, or a combination thereof.

In order to remove the patterned photoresist structures 110, the height of the conductive barrier layer 112 cannot be greater than the height of the patterned photoresist structures 110. In some embodiments, the conductive material may be deposited on the entire carrier substrate 102, and then a suitable planarization process is used to remove the conductive material that covers the patterned photoresist structures 110. In the embodiments, the height of the conductive barrier layer 112 is equal to the height of the patterned photoresist structures 110, as shown in FIG. 1B.

Still referring to FIG. 1B, the patterned photoresist structures 110 are removed to form a plurality of recesses 111 in the conductive barrier layer 112. Any suitable process may be used to remove the patterned photoresist structures 110, such as a dry etch, a wet etch, any other suitable process or a combination thereof. The cross-sectional profiles of the recesses 111 correspond to and are complementary to those of the patterned photoresist structures 110, as shown in FIG. 1B.

In addition, using the conductive material to form the conductive barrier layer 112 helps raise the good yield of the product and lower the manufacturing cost, which is discussed in detail below.

Next, a photoresist layer is formed on the conductive barrier layer 112 and filled into the recesses 111. Then, a photolithography process is performed to pattern the photoresist layer to form a second patterned photoresist layer 113 on the conductive barrier layer 112. As shown in FIG. 1C, the second patterned photoresist layer 113 exposes the recesses 111 and a portion of the conductive barrier layer 112. In such embodiments, the material and the formation method of the second patterned photoresist layer 113 are the same as those of the first patterned photoresist layer.

Next, the conductive barrier layer 112 is used as an electrode to perform an electroplating process such that a metal material is formed on the conductive barrier layer 112 and filled into the recesses 111. Then, the second patterned photoresist layer 113 is removed to form a first wiring layer 114 and a plurality of metal pillars 116 as shown in FIG. 1D.

Referring to FIG. 1D, the first wiring layer 114 includes a plurality of conductive contact pads 114a and a plurality of embedded wires 114b. The metal pillars 116 are in the recesses 111, and the cross-sectional profiles of the metal pillars 116 correspond to and are the same as the cross-sectional profiles of the recesses 111 as shown in FIG. 1D. Furthermore, each metal pillar 116 is formed on one of the conductive contact pads 114a and is in direct contact with the conductive contacting pad 114a.

The metal material may include nickel, aluminum, tungsten, copper, silver, gold or an alloy thereof. In the embodiments, the metal material is different from the conductive material, which can help to simplify the process and lower the manufacturing cost, which is discussed in more detail below.

In some other embodiments, the second patterned photoresist layer 113 can also not be formed. In such embodiments, the conductive barrier layer 112 can be used as an electrode to perform an electroplating process on the structure shown in FIG. 1B. Therefore, the metal material is formed on the conductive barrier layer 112 and filled into the recesses 111 so as to form a metal layer that completely covers the conductive barrier layer 112. Then, the metal layer is patterned to form the first wiring layer 114 and the plurality of metal pillars 116 as shown in FIG. 1D. In other words, in the embodiments, the process in FIG. 1C is omitted.

In the embodiments, the formation of the first wiring layer 114 and the metal pillars 116 adopts the steps of forming the second patterned photoresist layer 113 followed by performing the electroplating process. It is appreciated that compared to the pattern formed by the etch process, the pattern formed by the photolithography process is precise. Accordingly, the first wiring layer 114 obtained in the embodiments has finer wiring and thus it is helpful to increasing wiring density and miniaturizing circuit board structures.

In some embodiments, the width of the recesses 110 is very small or the aspect ratio of the recesses 111 is very high. In such embodiments, it is difficult to fill the recesses 111 with the metal material, thereby resulting in a poor thickness uniformity of the first wiring layer 114 and the metal pillars 116 or generating voids in the metal pillars 116 to reduce conductivity. In the embodiments, the first wiring layer 114 and the metal pillars 116 are formed using the electroplating process. Since the electroplating process has an excellent hole-filling ability, the formed first wiring layer 114 and the formed metal pillars 116 have good thickness uniformity and may reduce or avoid the voids appearing in the metal pillars 116. Therefore, even if the circuit board structure is miniaturized, the resulting circuit board structure may still have high reliability and high good yield.

Furthermore, if a non-conductive material (such as photoresist) is used to form a barrier layer, the barrier layer cannot be used as an electrode to perform the electroplating process. In this case, in order to use the electroplating process to form the first wiring layer 114 and the metal pillars 116, an additional conductive layer needs to be deposited on the barrier layer. Therefore, at least one additional deposition process has to be performed, which increases the steps of the process and the time and cost consumed by manufacture.

By comparison, in the embodiments, the conductive barrier layer 112 is used as an electrode to perform the electroplating process such that the steps of the process can be reduced and the time and cost consumed by manufacture can also be reduced.

In addition, in the embodiments, the first wiring layer 114 and the metal pillars 116 are formed simultaneously in the same electroplating process. Therefore, the steps of the process can be reduced further, thereby decreasing the manufacturing time and cost. Furthermore, in the embodiments, the materials of the first wiring layer 114 and the metal pillars 116 are the same and are formed simultaneously in the same electroplating process. As a result, there is no interface between the first wiring layer 114 and the metal pillars 116. In other words, the lattices or the atom arrangements of the first wiring layer 114 and the metal pillars 116 are identical. Hence, the physical connection between the first wiring layer 114 and the metal pillars 116 is too strong for them to become easily detached, which improves the reliability of the circuit board structure.

Referring to FIG. 1E, a dielectric layer 120 is formed on the first wiring layer 114, wherein the dielectric layer 120 completely covers the first wiring layer 114. The dielectric layer 120 is formed using any suitable dielectric material. For example, the dielectric layer 120 may include epoxy resin, bismaleimide triacine (BT), Ajinomoto build-up film (ABF film), poly phenylene oxide (PPE), polytetrafluorethylene (PTFE) or any other suitable dielectric material.

A suitable process may be selected by the selected dielectric material to form the dielectric layer 120, such as coating, thermocompression, laminating, any other suitable process, or a combination thereof.

Referring to FIG. 1F, after the dielectric layer 120 is formed, a plurality of blind holes 125 are formed in the dielectric layer 120. The blind holes 125 can expose a portion of the first wiring layer 114. A suitable drilling process may be selected by the selected dielectric material to form the blind holes 125. For example, the suitable drilling process may include laser drilling, mechanical drilling or a combination thereof.

Referring to FIG. 1G, a second metal material is deposited on the dielectric layer 120 and filled into the blind holes 125 to form a second wiring layer 124 and a plurality of conductive blind vias 122. The steps of forming the second wiring layer 124 and the conductive blind vias 122 are the same as those of forming the first wiring layer 114 and the metal pillars 116, which is not discussed in detail herein. The conductive blind vias 122 can electrically connect to the first wiring layer 114 and the second wiring layer 124, as shown in FIG. 1G.

The second metal material may be the same as or different from the metal material used to form the first wiring layer 114. Furthermore, the second metal material can be deposited using a suitable process, for example a chemical vapor deposition (CVD) process, physical vapor deposition (PVD) process, sputtering process, evaporation process, electroplating process, any other suitable deposition process, or a combination thereof.

In some embodiments, the second metal material is the same as the metal material used to form the first wiring layer 114. Therefore, both have the same material properties (e.g. conductivity or interatomic force) such that the electrical connection and physical connection between the first wiring layer 114 and the second wiring layer 124 becomes better and the reliability of the circuit board structure can be improved.

Referring to FIG. 1H, a protection layer 130 is formed on the second wiring layer 124. Next, the carrier substrate 102 is removed to detach the stripping layer 104 and the layers thereon from the carrier substrate 102 as shown in FIG. 1I.

The method of removing the substrate carrier 102 may include the attachment between the stripping layer 104 and the carrier substrate 102 being decreased by irradiation or heat and then the desired stripping force being applied to detach the stripping layer 104 from the carrier substrate 102.

In the step of removing the carrier substrate 102, the protection layer 130 can prevent the dielectric layer 120 from deformation or bending resulting from the stripping force, thereby raising the good yield of the product. The material of the protection layer 130 may be any suitable insulating material or dielectric material. The protection layer 130 may include a resin material with viscosity and rigidity, and a suitable formation process can be selected by the selected material. In some embodiments, the protection layer 130 is a thermosetting resin and is formed by coating followed by heat curing. In other embodiments, the protection layer 130 is a resin thin film and is attached to the dielectric layer 120 by lamination.

In some other embodiments, the stripping force is so small that the stripping force does not cause the dielectric layer 120 to deform or bend. In such embodiments, the process of forming the protection layer 130 is not needed, and neither is the subsequent process of removing the protection layer 130. Accordingly, the steps of the process and the material consumption can be reduced, and the manufacturing time and cost can be decreased further.

FIG. 1J illustrates a cross-sectional view of a circuit board unit after the removal of the carrier substrate. The circuit board unit includes the conductive barrier layer 112, the first wiring layer 114, the metal pillars 116, the dielectric layer 120, the second wiring layer 124 and the protection layer 130. The circuit board unit underlying the carrier substrate 102 is illustrated as shown in FIG. 1J.

After the removal of the carrier substrate 102, two circuit board units are generated. In the embodiments, a first circuit board unit above the carrier substrate 102 and a second circuit board unit below the carrier substrate 102 are symmetric to each other. As a result, after the first circuit board unit is flipped 180°, the structure of the first circuit board unit is the same as that of the second circuit board unit shown in FIG. 1J. In order to simplify the illustration, only the second circuit board unit is illustrated below.

In some embodiments, the protection layer 130 is removed as shown in FIG. 1K. The protection layer 130 may be removed using any suitable process (e.g. dry etch or wet etch), which is not discussed in detail herein.

Then, still referring to FIG. 1K, an etch process is performed to selectively remove the conductive barrier layer 112. After removing the conductive barrier layer 112, the metal pillars 116 protrude upward from an upper surface of the dielectric layer 120, and the upper surface of the dielectric layer 120 exposes the conductive contact pads 114a and the embedded wires 114b of the first wiring layer 114 as shown in FIG. 1K.

The conductive barrier layer 112 may be removed using any suitable etch process, for example a dry etch, a wet etch, or a combination thereof. In the embodiments, the conductive barrier layer 112 may be removed using a wet etch.

If the metal material is the same as the conductive material, the etch process cannot selectively remove the conductive material directly. In other words, an additional image transfer process needs to be performed so that the conductive material can be selectively removed. Hence, the process can be simplified and the manufacturing cost can be reduced by using a different metal material than the conductive material.

In order to selectively remove the conductive barrier layer 112 without removing the metal pillars 116 and the first wiring layer 114, the etch process may have high etch selectivity. In other words, if the etch process has a first etch rate R1 on the conductive material of the conductive barrier layer 112 and the etch process has a second etch rate R2 on the metal material of the metal pillars 116, and then R1/R2, the ratio of the first etch rate R1 to the second etch rate R2, is supposed to be greater. In some embodiments, R1/R2, the ratio of the first etch rate R1 to the second etch rate R2, is 10 to 1000. In some other embodiments, R1/R2, the ratio of the first etch rate R1 to the second etch rate R2, is 20 to 500. In some other embodiments, R1/R2, the ratio of the first etch rate R1 to the second etch rate R2, is 50 to 100.

A suitable etch process and etch condition may be selected by the conductive material of the conductive barrier layer 112 and the metal material of the metal pillars 116. To be more specific, in some embodiments, the conductive material of the conductive barrier layer 112 and the metal material of the metal pillars 116 are nickel and copper, respectively, and a wet etch process is performed at 25 to 75° C. with a concentrated nitric acid serving as an etch solvent. In such embodiments, R1/R2, the ratio of the first etch rate to the second etch rate R2, is about 100.

In some other embodiments, the conductive material of the conductive barrier layer 112 and the metal material of the metal pillars 116 are cobalt and copper, respectively, and a wet etch process is performed at 25 to 75° C. with a concentrated sulfuric acid serving as an etch solvent. In such embodiments, R1/R2, the ratio of the first etch rate to the second etch rate R2, is about 100.

According to some embodiments of the invention, since the etch process has high etch selectivity, the etching of the metal pillars 116 and the first wiring layer 114 may be significantly reduced or avoided such that the metal pillars 116 and the first wiring layer 114 have a uniform etch depth. In other words, even if the circuit board structure is miniaturized, the metal pillars 116 and the first wiring layer 114 can also have smooth surfaces and uniform surface resistances, which may thus improve the reliability and good yield of the product and is helpful to the miniaturization of the circuit board structure.

Referring to FIG. 1L, a first insulating passivation layer 140 is formed on the upper surface of the dielectric layer 120, and a second insulating passivation layer 150 is formed on the lower surface of the dielectric layer 120.

The first insulating passivation layer 140 includes a first opening 145, and the first opening 145 exposes the metal pillars 116, the conductive contact pads 114a and the embedded wires 114b as shown in FIG. 1L. The metal pillars 116 and the conductive contact pads 114a exposed by the first opening 145 can electrically connect to a chip or a die which is formed later. The embedded wires 114b exposed by the first opening 145 may be covered by an insulating material or package material which is formed later.

The second insulating passivation layer 150 includes a second opening 155, and the second opening 155 exposes a portion of the second wiring layer 124 as shown in FIG. 1L. The second wiring layer 124 exposed by the second opening 155 may electrically connect to an external device. So far, the manufacture of the circuit board structure 100 has been completed.

The first insulating passivation layer 140 has a first thickness T1, the second insulating passivation layer 150 has a second thickness T2, and the dielectric layer 120 has a third thickness T3 as shown in FIG. 1L.

The circuit board structure is required to be smaller and thinner. Nonetheless, if the third thickness T3 of the dielectric layer 120 gets too thin, the heat treatment (e.g. baking) in the process will result in warping or bending of the circuit board structure. In particular, when the wiring densities on the upside and the downside of the circuit board structure are different, the problem of warping or bending of the circuit board structure discussed above is more severe.

In the embodiments, by forming the second insulating passivation layer 140 and the second insulating passivation layer 150 on the upper surface and the lower surface of the dielectric layer 120 to applying a stress to the dielectric layer 120 to resist the bending stress, the circuit board structure can be significantly improved or prevented from warping or bending.

In order to generate a suitable stress, T1/T2, the ratio of the thickness T1 of the first insulating passivation layer 140 to the thickness T2 of the second insulating passivation layer 150, is controlled within a proper range. In some embodiments, T1/T2, the ratio of the thickness T1 of the first insulating passivation layer 140 to the thickness T2 of the second insulating passivation layer 150, is 0.5 to 2.

To be more specific, in some embodiments, if the circuit board bends upward, the thickness T2 of the second insulating passivation layer 150 is greater than the thickness T1 of the first insulating passivation layer 140. In such embodiments, T1/T2, the ratio of the first thickness T1 to the second thickness T2, is 0.5 to 1.

Conversely, in some other embodiments, if the circuit board bends downward, the thickness T1 of the first insulating passivation layer 140 is larger than the thickness T2 of the second insulating passivation layer 150. In such embodiments, T1/T2, the ratio of the first thickness T1 to the second thickness T2, is 1 to 2.

Moreover, if the first thickness T1 and/or the second thickness T2 are/is too small, the generated stress is insufficient to overcome the warping or the bending of the circuit board structure. Conversely, if the first thickness T1 and/or the second thickness T2 are/is too large, it is not good for thinning the circuit board structure. Therefore, the range of the first thickness T1 and/or the second thickness T2 may be adjusted by the third thickness T3 of the dielectric layer 120. In other words, T1/T3, the ratio of the first thickness T1 of the first insulating passivation layer 140 to the third thickness T3 of the dielectric layer 120, may be controlled within a proper range.

In some embodiments, T1/T3, the ratio of the first thickness T1 to the third thickness T3, is 0.1 to 20. In some other embodiments, T1/T3, the ratio of the first thickness T1 to the third thickness T3, is 1 to 10. In some other embodiments, T1/T3, the ratio of the first thickness T1 to the third thickness T3, is 2 to 5.

Still referring to FIG. 1L, some embodiments of the invention provides a circuit board structure 100. The circuit board structures 100 may include the dielectric layer 120, the first wiring layer 114, the plurality of metal pillars 116, second wiring layer 124, the plurality of conductive blind vias 122, the first insulating passivation layer 140 and the second insulating passivation layer 150.

The dielectric layer 120 has the upper surface and the lower surface opposite to each other. The first wiring layer 114 is embedded in the dielectric layer 120 and includes the plurality of conductive contact pads 114a and the plurality of embedded wires 114b. The conductive contact pads 114a are exposed on the upper surface of the dielectric layer 120. Each of the metal pillars 116 is formed on and is in direct contact with one of the conductive contact pads 114a. The second wiring layer 124 is formed on the lower surface of the dielectric layer 120. The conductive blind vias 122 are embedded in the dielectric layer 120, wherein the conductive blind vias 122 are used to electrically connect the first wiring layer 114 with the second wiring layer 124. The first insulating passivation layer 140 is formed on the upper surface of the dielectric layer 120 and includes at least one first opening 145. The first opening 145 exposes the metal pillars 116 and the conductive contact pads 114a. The second insulating passivation layer 150 is formed on the lower surface of the dielectric layer 120 and includes at least one second opening 155. The second opening 155 exposes a portion of the second wiring layer 124.

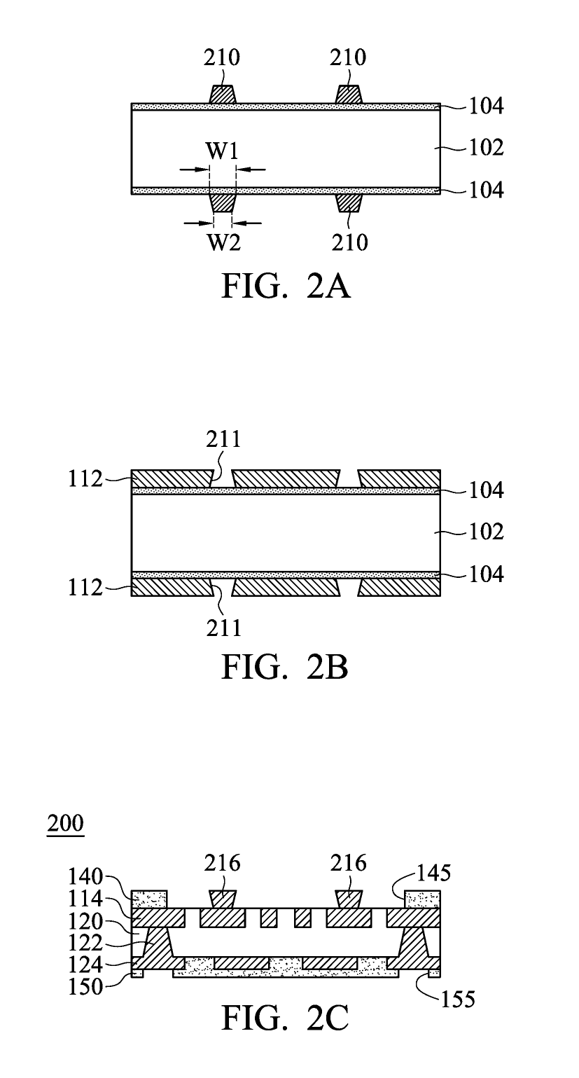

FIGS. 2A to 2C are cross-sectional views of various intermediate stages of forming a circuit board structure according to some embodiments. The components in FIGS. 2A to 2C the same as those of FIGS. 1A to 1L are represented by the same reference numerals. To simplify the illustration, the components and forming process steps thereof in FIG. 2A to 2C which are the same as those in FIGS. 1A to 1L are not discussed herein again.

Referring to FIG. 2A, a carrier substrate 102 whose upper surface and lower surface respectively have stripping layers 104 is provided, and a first patterned photoresist layer is formed on the upper surface and the lower surface of the carrier substrate 102. The first patterned photoresist layer includes a plurality of patterned photoresist structure 210 as shown in FIG. 2A.

In the embodiments, the processes performed on the upper surface and the lower surface of the carrier substrate 102 are both the same, and the shape and relative position of each component on the upper surface of the carrier substrate 102 are symmetric to each shape and relative position of each component on the lower surface of the carrier substrate 102 by using the carrier substrate 102 as a symmetric plane. In order to simplify the illustration, only the components on the lower surface of the carrier substrate 102 are discussed below.

FIG. 2A is similar to FIG. 1A. The difference is that the cross-sectional profiles of the patterned photoresist structures 210 and the cross-sectional profiles of the patterned photoresist structures 110 are different. Referring to FIG. 2A, in the embodiments, the patterned photoresist structures 210 on the lower surface of the carrier substrate 102 have inverted-trapezoid cross-sectional profiles.

The parameters (e.g. a photoresist material, a developer composition, exposure energy, exposure time, frequency of exposure, etc.) of the image transfer process may be adjusted to form the inverted trapezoid profiles of the patterned photoresist structures 210. In the embodiments, the inverted trapezoid profiles of the patterned photoresist structures 210 are formed by adjusting the exposure energy and the exposure time.

Referring to FIG. 2B, a conductive material is deposited on the carrier substrate 102 to form a conductive barrier layer 112 surrounding the patterned photoresist structures 210. Subsequently, the patterned photoresist structures 210 are removed to form a plurality of recesses 211 in the conductive barrier layer 112.

FIG. 2B is similar to FIG. 1B. The difference is that the cross-sectional profiles of the recesses 211 and the cross-sectional profiles of the recesses 111 are different. Referring to FIGS. 2A and 2B, the cross-sectional profiles of the recesses 211 correspond to and are complementary to the cross-sectional profiles of the patterned photoresist structures 210. Therefore, in the embodiments, the recesses on the lower surface of the carrier substrate 102 have inverted trapezoid cross-sectional profiles as shown in FIG. 2B.

Next, in some embodiments, the same steps of the process as those in FIGS. 1C to 1L are performed on the circuit board structure of FIG. 2B to form a circuit board structure 200 as shown in FIG. 2C.

In some other embodiments, a metal material can also be electroplated to form a metal layer and then the metal layer is patterned to form a circuit board structure similar to that of FIG. 1D. Next, the same steps of the process as those in FIGS. 1E to 1L are performed on the resulting circuit board structure to form the circuit board structure 200 as shown in FIG. 2C.

The circuit board structure 200 may include a dielectric layer 120, a first wiring layer 114, a plurality of metal pillars 216, a second wiring layer 124, a plurality of conductive blind vias 122, a first insulating passivation layer 140 and a second insulating passivation layer 150.

FIG. 2C is similar to FIG. 1L. The difference is that the cross-sectional profiles of the metal pillars 216 and the cross-sectional profiles of the metal pillars 116 are different. Referring to FIGS. 2C, the cross-sectional profiles of the metal pillars 216 correspond to and are identical to the cross-sectional profiles of the recesses 210. Therefore, in the embodiments, the metal pillars 216 on the lower surface of the carrier substrate 102 have inverted trapezoid cross-sectional profiles as shown in FIG. 2C.

In addition, in the embodiments, the circuit board structure 200 on the upper surface of the carrier substrate 102 is symmetric to the circuit board structure 200 on the lower surface of the carrier substrate 102. When the circuit board structure 200 on the upper surface is flipped, the resulting structure is identical to the circuit board structure 200 on the lower surface of the carrier substrate 102. Therefore, the metal pillars 216 of the circuit board structure 200 on the upper surface of the carrier substrate 102 have inverted trapezoid cross-sectional profiles as well.

In the embodiments, the metal pillars 216 of the circuit board structure 200 have inverted trapezoid cross-sectional profiles. Compared to rectangular cross-sectional profiles, the inverted trapezoid cross-sectional profiles can have larger contact areas and adhesion force between the metal pillars 216 and solder balls which are used to electrically connect to external components. Furthermore, compared to rectangular cross-sectional profiles, the inverted trapezoid cross-sectional profiles can make it harder for the metal pillars 216 to delaminate from the solder balls. As a result, the good yield of products can be improved further.

It can be appreciated that the cross-sectional profiles of the metal pillars 216 correspond to and are complementary to the cross-sectional profiles of the patterned photoresist structures 210. Therefore, the desired cross-sectional profiles of the metal pillars 216 may be obtained by changing the cross-sectional profiles of the patterned photoresist structures 210.

Referring to FIG. 2A, the cross-sectional profiles of the patterned photoresist structures 210 under the carrier substrate 102 are inverted trapezoid. An upper side of the inverted trapezoid (i.e. a side close to the carrier substrate 102) has a maximum width W1, and a lower side of the inverted trapezoid (i.e. a side away from the carrier substrate 102) has a minimum width W2.

If W1/W2, the ratio of the maximum width W1 to the minimum width W2, is too small, the levels of increasing the contact area and the adhesion force will be insufficient so that the good yield of the product cannot be improved significantly. Conversely, if W1/W2, the ratio of the maximum width W1 to the minimum width W2, is too large, it will be easy to create voids or other defects in the resulting metal pillars so that the reliability and the good yield of the product are decreased. Therefore, W1/W2, the ratio of the maximum width W1 to the minimum width W2, may be controlled within a suitable range.

In some embodiments, W1/W2, the ratio of the maximum width W1 to the minimum width W2, is from 0.5 to 10. In some other embodiments, W1/W2, the ratio of the maximum width W1 to the minimum width W2, is from 1 to 5. In some other embodiments, W1/W2, the ratio of the maximum width W1 to the minimum width W2, is 2 to 3.

Furthermore, if the maximum width W1 is too small, it will be difficult to remove the patterned photoresist structures and form the metal pillars. If the maximum width W1 is too large, it will be disadvantageous for the miniaturization of the circuit board structure. In some embodiments, the maximum width W1 is 10-50 μm.

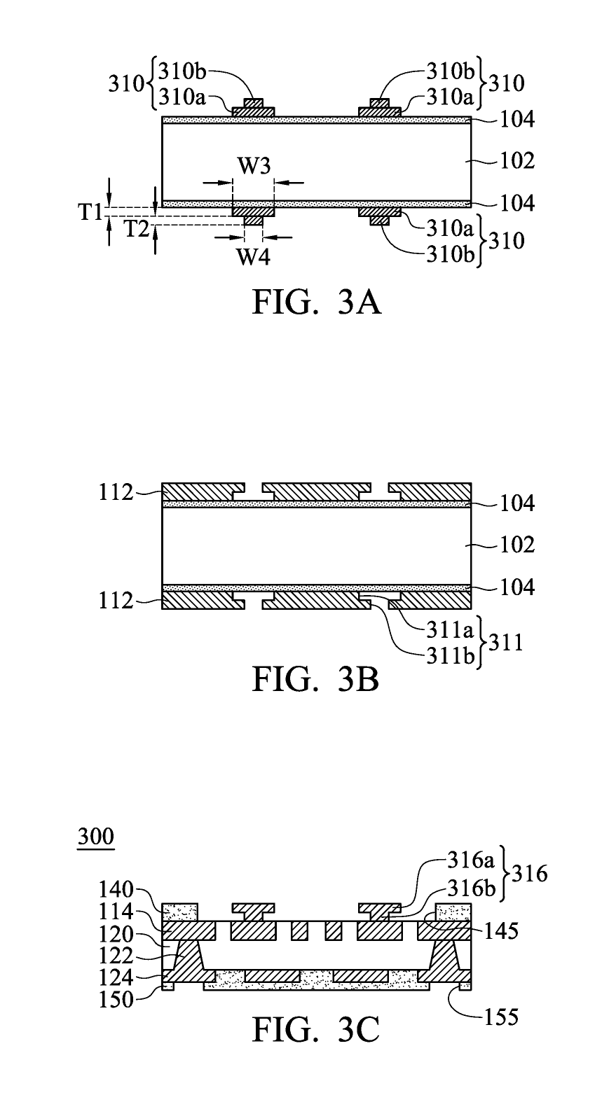

FIGS. 3A to 3C are cross-sectional views of various intermediate stages of forming a circuit board structure according to some embodiments. The components in FIGS. 3A to 3C the same as those of FIGS. 1A to 1L are represented by the same reference numerals. To simplify the illustration, the components and forming process steps thereof in FIG. 3A to 3C which are the same as those in FIGS. 1A to 1L are not discussed herein again.

In the embodiments, the processes performed on the upper surface and the lower surface of the carrier substrate 102 are both the same, and the shape and relative position of each component on the upper surface of the carrier substrate 102 are symmetric to each shape and relative position of each component on the lower surface of the carrier substrate 102 by using the carrier substrate 102 as a symmetric plane. In order to simplify the illustration, only the components on the lower surface of the carrier substrate 102 are discussed below.

FIG. 3A is similar to FIG. 1A. The difference is that the cross-sectional profiles of the patterned photoresist structures 310 and the cross-sectional profiles of the patterned photoresist structures 110 are different. Referring to FIG. 3A, in the embodiments, the patterned photoresist structures 310 on the lower surface of the carrier substrate 102 have T-shaped cross-sectional profiles. The T-shaped patterned photoresist structures 310 have a first part 310a and a second part 310b.

In the embodiments, a first image transfer process is performed to form the first portion 310a of the patterned photoresist structures 310. Then, a second image transfer process is performed to form the second portion 310b of the patterned photoresist structures 310. As a result, the formed patterned photoresist structures 310 have T-shaped cross-sectional profiles.

Referring to FIG. 3B, a plurality of recesses 311 is formed in the conductive barrier layer 112. FIG. 3B is similar to FIG. 1B. The difference is that the cross-sectional profiles of the recesses 311 and the cross-sectional profiles of the recesses 111 are different. Referring to FIGS. 3A and 3B, the cross-sectional profiles of the recesses 311 correspond to and are complementary to the cross-sectional profiles of the patterned photoresist structures 310. Therefore, in the embodiments, the recesses 311 on the lower surface of the carrier substrate 102 have T-shaped cross-sectional profiles as shown in FIG. 3B. The T-shaped recesses 311 have a first part 311a and a second part 311b.

Next, in some embodiments, the same steps of the process as those in FIGS. 1C to 1L are performed on the circuit board structure of FIG. 3B to form a circuit board structure 300 shown in FIG. 3C.

In some other embodiments, a metal material may also be electroplated first to form a metal layer, and then the metal layer is patterned to form a circuit board structure similar to that in FIG. 1D. Then, the same steps of the process as those in FIGS. 1E to 1L are performed on the resulting circuit board structure to form the circuit board structure 300 as shown in FIG. 3C.

FIG. 3C is similar to FIG. 1L. The difference is that the cross-sectional profiles of the metal pillars 316 and the cross-sectional profiles of the metal pillars 116 are different. Referring to FIGS. 3C, the cross-sectional profiles of the metal pillars 316 correspond to and are identical to the cross-sectional profiles of the recesses 311. Therefore, in the embodiments, the metal pillars 316 on the lower surface of the carrier substrate 102 have T-shaped cross-sectional profiles as shown in FIG. 3C. The T-shaped metal pillars 316 have a first part 316a and a second part 316b.

In addition, in the embodiments, the circuit board structure 300 on the upper surface of the carrier substrate 102 is symmetric to the circuit board structure 300 on the lower surface of the carrier substrate 102. Therefore, when the circuit board structure 300 on the upper surface is flipped, the metal pillars 316 have the T-shaped cross-sectional profiles as well.

In the embodiments, the metal pillars 316 of the circuit board structure 300 have the T-shaped cross-sectional profiles. Compared to rectangular cross-sectional profiles, the T-shaped cross-sectional profiles can have larger contact areas and larger adhesion force between the metal pillars 216 and solder balls which are used to electrically connect to external components. Furthermore, compared to rectangular cross-sectional profiles, the T-shaped cross-sectional profiles can make it harder for the metal pillars 316 to delaminate from the solder balls. As a result, the good yield and the reliability of the product can be improved further.

Referring to FIG. 3A, the cross-sectional profiles of the patterned photoresist structures 310 under the carrier substrate 102 are T-shaped. The first part 310a of the T-shape (i.e. the side close to the carrier substrate 102) has a maximum width W3, and the second part 310b of the T-shaped (i.e. the side away from the carrier substrate 102) has a minimum width W4.

If W3/W4, the ratio of the maximum width W3 to the minimum width W4, is too small, the levels of increasing the contact area and the adhesion force will be insufficient so that the good yield of the product cannot be improved significantly. Conversely, if W3/W4, the ratio of the maximum width W3 to the minimum width W4, is too large, it will be easy to create voids or other defects in the resulting metal pillars so that the reliability and the good yield of the product are decreased. Therefore, W3/W4, the ratio of the maximum width W3 of the T-shape to the minimum width W4 of the T-shape, may be controlled within a suitable range. In some embodiments, W3/W4, the ratio of the maximum width W3 to the minimum width W4, is 1.5 to 5.

Furthermore, if the maximum width W3 is too small, it will be difficult to remove the patterned photoresist structures and to form the metal pillars. If the maximum width W3 is too large, it will be disadvantageous for the miniaturization of the circuit board structure. In some embodiments, the maximum width W3 is 10 to 50 μm.

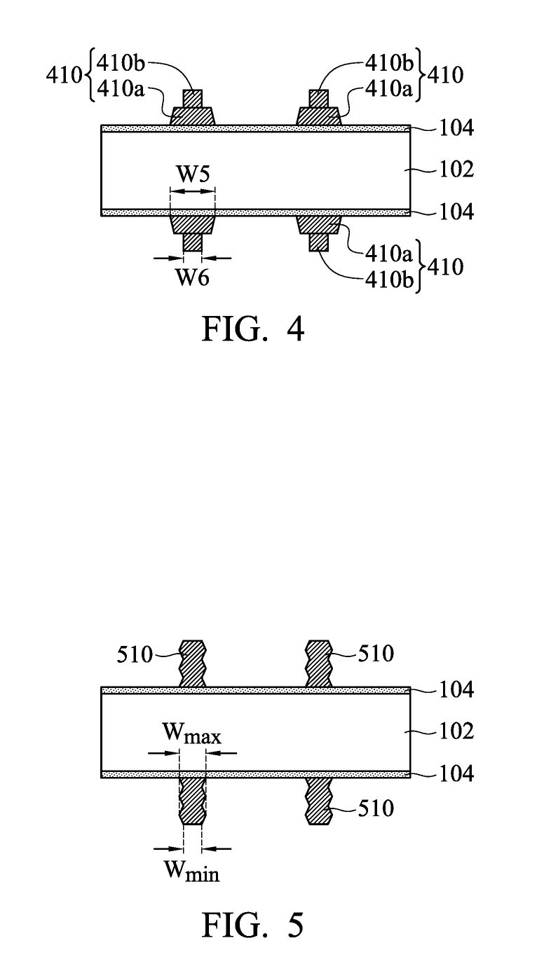

FIG. 4 is a cross-sectional view of a patterned photoresist structure 410 of some embodiments. FIG. 4 is similar to FIG. 1A. The difference is that the cross-sectional profiles of the patterned photoresist structures 410 and the cross-sectional profiles of the patterned photoresist structures 110 are different. Referring to FIG. 4, in the embodiments, the patterned photoresist structures 410 on the lower surface of the carrier substrate 102 have T-like shape cross-sectional profiles. The T-like shape patterned photoresist structures 410 have a first part 410a of an inverted trapezoid and a second part 410b of an rectangle. Consequently, the T-like shape can also be regarded as a combination of the inverted trapezoid and the rectangle.

Similar to the above T-shaped cross-sectional profiles, the T-like shape cross-sectional profiles can also further raise the good yield and the reliability of the product. The first part 410a of the patterned photoresist structures 410 (i.e. the side close to the carrier substrate 102) has a maximum width W5, and the second part 410b of the patterned photoresist structures 410 (i.e. the side away from the carrier substrate 102) has a minimum width W6.

W5/W6, the ratio of the maximum width W5 of the T-like shape to the minimum width W6 of the T-like shape, may be controlled within a suitable range. In some embodiments, the range of W5/W6, the ratio of the maximum width W5 of the T-like shape to the minimum width W6 of the T-like shape, may be the same as that of W3/W4. In some embodiments, the range of the maximum width W5 may be the same as the above range of W3.

FIG. 5 is a cross-sectional view of patterned photoresist structures 510 of some embodiments. FIG. 5 is similar to FIG. 1A. The difference is that the cross-sectional profiles of the patterned photoresist structures 510 and the cross-sectional profiles of the patterned photoresist structures 110 are different. Referring to FIG. 5, in the embodiments, the patterned photoresist structures 510 on the lower surface of the carrier substrate 102 have zigzag cross-sectional profiles.

In the embodiments, the zigzag cross-sectional profiles of the patterned photoresist structures 510 are formed by adjusting the exposure energy and the exposure time.

Compared to rectangular cross-sectional profiles, the zigzag cross-sectional profiles can have larger contact areas and larger adhesion force between the metal pillars and solder balls which are used to electrically connect to external components. Therefore, the good yield and the reliability of the product can be raised further.

The zigzag patterned photoresist structure 510 have a maximum width Wₘₐₓ and a minimum width W. as shown in FIG. 5.

If Wₘₐₓ/Wₘᵢₙ, the ratio of the maximum width Wₘₐₓ to the minimum width Wₘᵢₙ, is too small, the levels of increasing the contact area and the adhesion force will be insufficient so that the good yield of the product cannot be improved significantly. Conversely, if Wₘₐₓ/Wₘᵢₙ, the ratio of the maximum width Wₘₐₓ to the minimum width Wₘᵢₙ, is too large, it will be easy to create voids or other defects in the resulting metal pillars so that the reliability and the good yield of the product are decreased. Therefore, Wₘₐₓ/Wₘᵢₙ, the ratio of the maximum width Wₘₐₓ of the zigzag to the minimum width Wₘᵢₙ of the zigzag, may be controlled within a suitable range. In some embodiments, Wₘₐₓ/Wₘᵢₙ, the ratio of the maximum width Wₘₐₓ of the zigzag to the minimum width Wₘᵢₙ of the zigzag, is 1 to 3.

It can be appreciated that the cross-sectional profiles and the numbers of the patterned photoresist structures shown in FIGS. 1A, 2A, 3A, 4 and 5 are only used for illustration, but not used to limit the invention.

For example, in some embodiments, for the patterned photoresist structures under the carrier substrate, the cross-sectional profile of each patterned photoresist structure may be rectangle, inverted trapezoid, T-shape, inverted L-shape, zigzag, or a combination thereof. In other words, the cross-sectional profiles of all the patterned photoresist structures are the same. In such embodiments, the cross-sectional profile of each formed metal pillar may be rectangle, inverted trapezoid, T-shape, inverted L-shape, zigzag, or a combination thereof.

In some other embodiments, for the patterned photoresist structures under the carrier substrate, each patterned photoresist structure may have a different cross-sectional profile. Namely, the cross-sectional profile of each patterned photoresist structure may independently be a rectangle, inverted trapezoid, T-shape, inverted L-shape, zigzag, or a combination thereof. In such embodiments, the cross-sectional profile of each formed metal pillar may independently be a rectangle, inverted trapezoid, T-shape, inverted L-shape, zigzag, or a combination thereof.

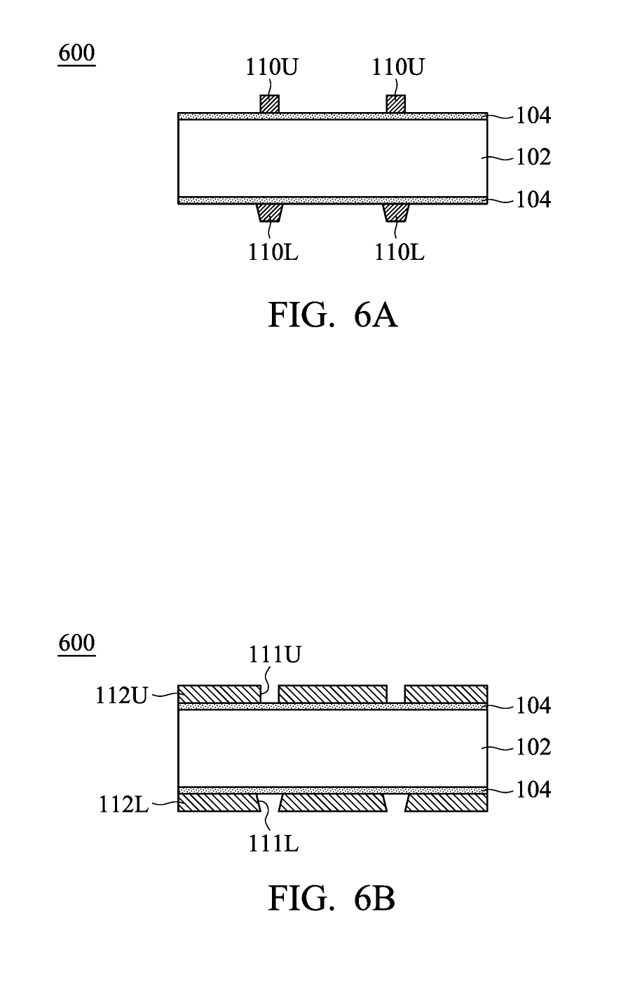

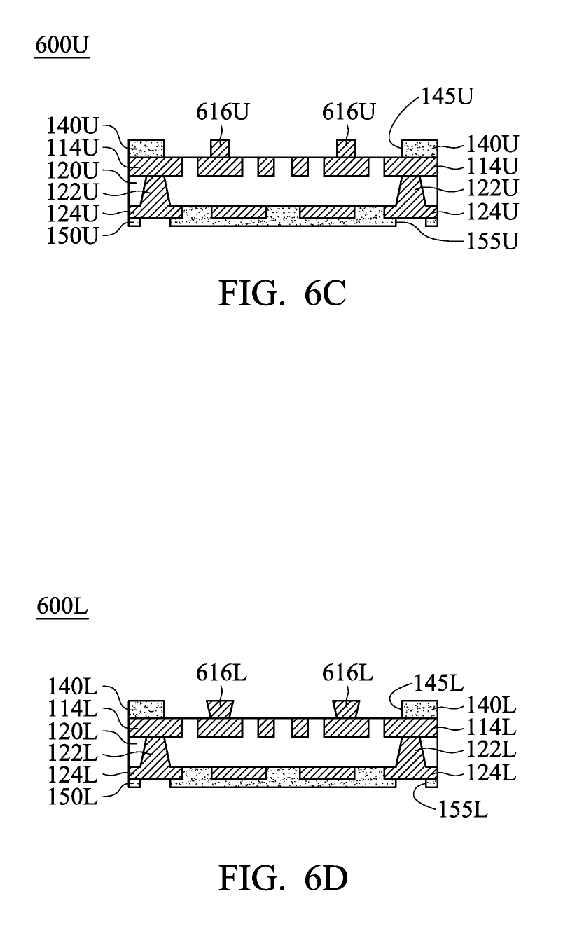

FIGS. 6A to 6C are cross-sectional views of various intermediate stages of forming a circuit board structure according to some embodiments. The components in FIGS. 6A to 6C the same as those of FIGS. 1A to 1L are represented by the same reference numerals. To simplify the illustration, the components and forming process steps thereof in FIG. 6A to 6C which are the same as those in FIGS. 1A to 1L are not discussed herein again.

In the embodiments, the components on the upper surface and the lower surface of the carrier substrate 102 are not symmetric to each other. For better illustration, the components on the upper surface and the lower surface of the carrier substrate 102 are respectively referred to as “the upper component” and “the lower component”. For example, the patterned photoresist structures on the upper surface of the carrier substrate 102 are referred to as “the upper patterned photoresist structures”, and the reference numerals thereof are 110U. On the other hand, the patterned photoresist structures on the lower surface of the carrier substrate 102 are referred to as “the lower patterned photoresist structures” and the reference numerals thereof are 110L.

FIG. 6A is similar to FIG. 1A. The difference is that the cross-sectional profiles of the patterned photoresist structures 110U and the cross-sectional profiles of the patterned photoresist structures 110L are different. Referring to FIG. 6A, in the embodiments, the patterned photoresist structures 110U have rectangular cross-sectional profiles and the patterned photoresist structures 110L have inverted trapezoid cross-sectional profiles.

Referring to FIG. 6B, a plurality of upper recesses 111U are formed in an upper conductive barrier layer 112U, and a plurality of lower recesses 111L are formed in a lower conductive barrier layer 112L. Referring to FIG. 6A, in the embodiments, the upper recesses 111U have rectangular cross-sectional profiles, and the lower recesses 111L have inverted trapezoid cross-sectional profiles.

Then, in some embodiments, the same steps of the process as those in FIGS. 1C to 1I are performed on the circuit board structure 600 of FIG. 6B.

In some other embodiments, a metal material may first be electroplated to form a metal layer, and then the metal layer is patterned to form a circuit board structure similar to that shown in FIG. 1D. Next, the same steps of the process as those in FIGS. 1E to 1I are performed on the resulting circuit board structure.

After removing the carrier substrate, two circuit board units are generated. In the embodiments, the upper circuit board unit above the carrier substrate 102 and the lower circuit board unit below the carrier substrate 102 are different structures from each other.

Next, the same steps of the process as those in FIGS. 1J to 1L are performed on the upper circuit board unit above the carrier substrate 102 to form an upper circuit board structure 600U as shown in FIG. 6C. In the embodiments, the patterned photoresist structures 110U and the patterned photoresist structures 110 of FIG. 1A are the same. Therefore, the resulting upper circuit board structure 600U and the circuit board structure 100 of FIG. 1L are the same.

The upper circuit board structure 600U may include an upper dielectric layer 120U, an upper first wiring layer 114U, a plurality of upper metal pillars 616U, an upper second wiring layer 124U, a plurality of upper conductive blind vias 122U, an upper first insulating passivation layer 140U and an upper second insulating passivation layer 150U. The upper first insulating passivation layer 140U has an upper first opening 145U which exposes the upper metal pillars 616U and a portion of the upper first wiring layer 114U. The upper second insulating passivation layer 150U has an upper second opening 155U which exposes a portion of the upper second wiring layer 124U.

On the other hand, the same steps of the process as those in FIGS. 1J to 1L are performed on the lower circuit board unit under the carrier substrate 102 to form a lower circuit board structure 600L as shown in FIG. 6D. In the embodiments, the patterned photoresist structures 110L and the patterned photoresist structures 210 of FIG. 2A are the same. Therefore, the resulting lower circuit board structure 600L and the circuit board structure 200 of FIG. 2C are the same.

The lower circuit board structure 600L may include a lower dielectric layer 120L, a lower first wiring layer 114L, a plurality of lower metal pillars 616L, a lower second wiring layer 124L, a plurality of lower conductive blind vias 122L, a lower first insulating passivation layer 140L and a lower second insulating passivation layer 150L. The lower first insulating passivation layer 140L has a lower first opening 145L which exposes the lower metal pillars 616L and a portion of the lower first wiring layer 114L. The lower second insulating passivation layer 150L has a lower second opening 155L which exposes a portion of the lower second wiring layer 124L.

In the embodiments, the patterned photoresist structures with different cross-sectional profiles are respectively formed on the upper surface and the lower surface of the carrier substrate. Two kinds of circuit board structures which have metal pillars with different cross-sectional profiles (e.g. the metal pillars 616U of FIG. 6C and the metal pillars 616L of FIG. 6D) may be manufactured at the same time, such that the manufacturing time and cost can be saved, and the flexibility and the efficiency of the manufacture process can be increased.

It can be appreciated that the cross-sectional profiles of the patterned photoresist structures and the numbers of the cross-sectional profiles shown in FIG. 6A are only used for illustration, but not used to limit the invention.

For example, in some embodiments, the cross-sectional profiles of the upper patterned photoresist structures and the lower patterned photoresist structures may independently be a rectangle, trapezoid, inverted trapezoid, T-shape, inverted T-shape, L-shape, inverted L shape, zigzag, or a combination thereof, and the upper patterned photoresist structures and the lower patterned photoresist structures have different cross-sectional profiles.

In some other embodiments, in addition to the fact that the upper patterned photoresist structures and the lower patterned photoresist structures have different cross-sectional profiles, for the patterned photoresist structures on the same side (e.g. on the upper surface) of the carrier substrate, each of the patterned photoresist structures may have cross-sectional profiles different from each other.

To sum up, some embodiments of the invention provide a circuit board structure with high good yield and high reliability, and provide a method of forming the circuit board structure with low cost and high efficiency.

To be specific, the advantages of the circuit board structures and the methods for forming the same which are provided by the embodiments of the invention at least include:
(1) The first insulating passivation layer and the second insulating passivation layer are formed on the upper surface and the lower surface of the dielectric layer, respectively, and the thicknesses of the dielectric layer, the first insulating passivation layer and the second insulating passivation layer are controlled within specific ranges. Therefore, the warping or bending of the circuit board structures can be significantly reduced or avoided.
(2) The metal pillars have non-rectangular cross-sectional profiles. Therefore, the contact areas and the adhesion force between the solder balls and the metal pillars may be increased. Furthermore, the metal pillars are harder to delaminate from the solder balls such that the good yield and the reliability of the product can be raised further.
(3) The conductive barrier layer is used as an electrode to perform the electroplating process. Therefore, the steps of the process can be reduced and the manufacturing time and cost can be reduced.
(4) The first wiring layer and the metal pillars are formed simultaneously using the electroplating process. Therefore, the thickness uniformities of the formed first wiring layer and the formed metal pillars are good, and the physical contact between the first wiring layer and the metal pillars is so strong that they are not easy to be delaminated. Consequently, even if the circuit board structure is miniaturized, the resulting circuit board structure can still have high reliability and high good yield.
(5) The conductive barrier layer is removed using an etch process with high etch selectivity so that the metal pillars and the first wiring layer have a uniform etch depth. Therefore, the reliability and the good yield of the product can be improved, and it is good for the miniaturization of the circuit board structure.
(6) The patterned photoresist structures with different cross-sectional profiles are formed on the upper surface and the lower surface of the carrier substrate, respectively. As a result, two kinds of circuit board structures with different cross-sectional profiles may be formed simultaneously such that the manufacturing time and cost can be saved, and the flexibility and the efficiency of the manufacture process are increased.
(7) The methods of forming the circuit board structures provided by the embodiments of the invention can easily be integrated into the existing process of forming circuit board structure and does not need an additional replacement or modification of manufacturing equipment. Under the premise that the complexity and the cost of the process may be reduced, the reliability and the good yield of the circuit board structures may be effectively improved.

Although the invention has provided several better embodiments as disclosed above, they are not used to limit the present invention. Those skilled in the art may make various changes, substitutions, and alterations herein without departing from the spirit and scope of the present invention. Hence, the limitations of the present invention should depend on the accompanying claims.

What is claimed is:

1. A circuit board structure, comprising:
a dielectric layer having an upper surface and a lower surface;
a first wiring layer embedded in the dielectric layer, wherein the first wiring layer comprises a plurality of conductive contact pads, and the conductive contact pads are exposed on the upper surface of the dielectric layer;
a plurality of metal pillars, wherein each of the metal pillars is formed on and is in direct contact with one of the conductive contact pads;
a first insulating passivation layer formed on the upper surface of the dielectric layer, wherein the first insulating passivation layer comprises a first opening, and the first opening exposes the plurality of metal pillars and the plurality of conductive contact pads; and
a second insulating passivation layer formed on the lower surface of the dielectric layer, wherein the second insulating passivation layer comprises a second opening.

2. The circuit board structure as claimed in claim 1, wherein a cross-sectional profile of each of the metal pillars is a rectangle, an inverted trapezoid, a T-shape, an inverted L-shape, a zigzag, or a combination thereof.

3. The circuit board structure as claimed in claim 1, wherein a cross-sectional profile of one of the metal pillars has a first shape, a cross-sectional profile of another one of the metal pillars has a second shape that is different from the first shape, and the first shape and the second shape are independently a rectangle, an inverted trapezoid, a T-shape, an inverted L-shape, a zigzag, or a combination thereof.

4. The circuit board structure as claimed in claim 1, wherein a cross-sectional profile of each of the metal pillars is an inverted trapezoid, the inverted trapezoid has a maximum width W1 and a minimum width W2, and W1/W2, a ratio of the maximum width W1 of the inverted trapezoid to the minimum width W2 of the inverted trapezoid, is from 0.5 to 10.

5. The circuit board structure as claimed in claim 1, wherein a cross-sectional profile of each of the metal pillars is a T-shape, the T-shape has a maximum width W3 and a minimum width W4, and W3/W4, a ratio of the maximum width W3 of the T-shape to the minimum width W4 of the T shape, is from 1.5 to 5.

6. The circuit board structure as claimed in claim 1, wherein a cross-sectional profile of each of the metal pillars is a zigzag, the zigzag has a maximum width Wₘₐₓ and a minimum width Wₘᵢₙ, and Wₘₐₓ/Wₘᵢₙ, a ratio of the maximum width Wₘₐₓ of the zigzag to the minimum width Wₘᵢₙ of the zigzag, is from 1 to 3.

7. The circuit board structure as claimed in claim 1, wherein the first insulating passivation layer has a first thickness T1, the second insulating passivation layer has a second thickness T2, and T1/T2, a ratio of the first thickness T1 to the second thickness T2, is from 0.5 to 2.

8. The circuit board structure as claimed in claim 7, wherein the dielectric layer has a third thickness T3, and T1/T3, a ratio of the first thickness T1 to the third thickness T3, is from 0.1 to 20.

9. The circuit board structure as claimed in claim 1, further comprising:
a second wiring layer formed on the lower surface of the dielectric layer, wherein a portion of the second wiring layer is exposed in the second opening of the second insulating passivation layer; and
a plurality of conductive blind vias embedded in the dielectric layer, wherein the plurality of conductive blind vias are electrically connected to the first wiring layer and the second wiring layer.

10. A method of forming a circuit board structure, comprising:
forming a first patterned photoresist layer on a carrier substrate, wherein the first patterned photoresist layer comprises a plurality of patterned photoresist structures;
depositing a conductive material on the carrier substrate to form a conductive barrier layer surrounding the plurality of patterned photoresist structures, wherein the conductive barrier layer and the patterned photoresist structures are the same height;
removing the plurality of patterned photoresist structures to form a plurality of recesses in the conductive barrier layer;
electroplating a metal material on the conductive barrier layer and filling the metal material into the plurality of recesses to form a plurality of metal pillars and a first wiring layer, wherein the plurality of metal pillars are in the plurality of recesses, and the first wiring layer comprises a plurality of conductive contact pads, and wherein the metal material is different from the conductive material;
forming a dielectric layer on the first wiring layer, wherein the dielectric layer covers the first wiring layer;
removing the carrier substrate;
performing an etch process to remove the conductive barrier layer, wherein the plurality of metal pillars protrude from an upper surface of the dielectric layer, and the upper surface of the dielectric layer exposes the plurality of conductive contact pads;
forming a first insulating passivation layer on the upper surface of the dielectric layer, wherein the first insulating passivation layer has a first opening, and the first opening exposes the plurality of metal pillars and the plurality of conductive contact pads; and
forming a second insulating passivation layer on a lower surface of the dielectric layer, wherein the second insulating passivation layer comprises a second opening.

11. The method of forming a circuit board structure as claimed in claim 10, wherein the conductive material comprises nickel, cobalt, zinc, aluminum, graphite, a conductive polymer, or a conductive metal oxide.

12. The method of forming a circuit board structure as claimed in claim 10, wherein the metal material comprises nickel, aluminum, tungsten, copper, silver, gold or an alloy thereof.

13. The method of forming a circuit board structure as claimed in claim 10, wherein the etch process has a first etch rate R1 on the conductive material, the etch process has a second etch rate R2 on the metal material, and R1/R2, a ratio of the first etch rate R1 to the second etch rate R2, is from 10 to 1000.

14. The method of forming a circuit board structure as claimed in claim 10, wherein the etch process is a wet etch process.

15. The method of forming a circuit board structure as claimed in claim 10, wherein a cross-sectional profile of each of the patterned photoresist structures is a rectangle, an inverted trapezoid, a T-shape, an inverted L-shape, a zigzag, or a combination thereof.

16. The method of forming a circuit board structure as claimed in claim 10, further comprising:
forming a plurality of conductive blind vias in the dielectric layer after the formation of the dielectric layer;
forming a second wiring layer on the dielectric layer, wherein a portion of the second wiring layer is exposed in the second opening of the second insulating passivation layer, and the plurality of conductive blind vias are electrically connected to the first wiring layer and the second wiring layer; and
removing the carrier substrate after the formation of the second wiring layer.

17. The method of forming a circuit board structure as claimed in claim 10, wherein before the electroplating of the metal material, the method further comprises:
forming a second patterned photoresist layer on the conductive barrier layer, wherein the second patterned photoresist layer exposes the plurality of recesses and a portion of the conductive barrier layer.

18. A method of forming a circuit board structure, comprising:
forming an upper patterned photoresist layer on an upper surface of a carrier substrate, and forming a lower patterned photoresist layer on a lower surface of the carrier substrate, wherein the upper patterned photoresist layer comprises a plurality of upper patterned photoresist structures, and the lower patterned photoresist layer comprises a plurality of lower patterned photoresist structures;
depositing a conductive material on the upper surface and the lower surface of the carrier substrate to form an upper conductive barrier layer surrounding the plurality of upper patterned photoresist structures and to form a lower conductive barrier layer surrounding the plurality of lower patterned photoresist structures, wherein the upper conductive barrier layer and the plurality of upper patterned photoresist structures have a first height, and the lower conductive barrier layer and the plurality of lower patterned photoresist structures have a second height;
removing the plurality of upper patterned photoresist structures and the plurality of lower patterned photoresist structures to form a plurality of upper recesses in the upper conductive barrier layer and to form a plurality of lower recesses in the lower conductive barrier layer;
electroplating a metal material on the upper conductive barrier layer and filling the metal material into the plurality of upper recesses to form a plurality of upper metal pillars and an upper wiring layer;
electroplating the metal material on the lower conductive barrier layer and filling the metal material into the plurality of lower recesses to form a plurality of lower metal pillars and a lower wiring layer;
forming an upper dielectric layer on the upper wiring layer, and forming a lower dielectric layer on the lower wiring layer;
removing the carrier substrate to form an upper circuit board unit that comprises the upper conductive barrier layer, the plurality of upper metal pillars, the upper wiring layer and the upper dielectric layer, and to form a lower circuit board unit that comprises the lower conductive barrier layer, the plurality of lower metal pillars, the lower wiring layer and the lower dielectric layer;
performing an etch process to remove the upper conductive barrier layer of the upper circuit board unit and to remove the lower conductive barrier layer of the lower circuit board unit;
forming an upper first insulating passivation layer on an upper surface of the upper circuit board unit, wherein the upper first insulating passivation layer has an upper first opening, and the upper first opening exposes the plurality of upper metal pillars and a portion of the upper wiring layer;
forming an upper second insulating passivation layer on a lower surface of the upper circuit board unit, wherein the upper second insulating passivation layer comprises an upper second opening;
forming a lower first insulating passivation layer on an upper surface of the lower circuit board unit, wherein the lower first insulating passivation layer has a lower first opening, and the lower first opening exposes the plurality of lower metal pillars and a portion of the lower wiring layer; and
forming a lower second insulating passivation layer on a lower surface of the lower circuit board unit, wherein the lower second insulating passivation layer comprises a lower second opening.

19. The method of forming a circuit board structure as claimed in claim 18, wherein a cross-sectional profile of the plurality of upper patterned photoresist structures is different from a cross-sectional profile of the plurality of lower patterned photoresist structures.

20. The method of forming a circuit board structure as claimed in claim 18, wherein a cross-sectional profile of the plurality of upper patterned photoresist structures and a cross-sectional profile of the plurality of lower patterned photoresist structures are not symmetric to each other.

21. The method of forming a circuit board structure as claimed in claim 18, wherein the plurality of upper metal pillars, the upper wiring layer, the plurality of lower metal pillars, and the lower wiring layer are formed at the same time during the same electroplating process.
